(19) United States
(12) Patent Application Publication
(10) Pub. No.: US 2019/0097063 A1
(43) Pub. Date: Mar. 28, 2019

(54) ESL TFT SUBSTRATE AND FABRICATION METHOD THEREOF

(71) Applicant: Shenzhen China Star Optoelectronics Semiconductor Display Technology Co., Ltd., Shenzhen City (CN)

(72) Inventor: Longqiang Shi, Shenzhen City (CN)

(21) Appl. No.: 15/742,038

(22) PCT Filed: Dec. 4, 2017
(86) PCT No.: PCT/CN2017/114428

§ 371 Date: Jan. 5, 2018

(30) Foreign Application Priority Data
Sep. 28, 2017 (CN) 201710900781.3

(51) Int. Cl. H01L 29/786; H01L 27/12; H01L 21/02; H01L 21/383; H01L 29/66; H01L 29/24

(52) U.S. Cl. CPC H01L 29/78618; H01L 27/1225; H01L 27/127; H01L 21/02565; H01L 29/78696; H01L 29/66969; H01L 29/24; H01L 29/78633; H01L 29/7869; H01L 21/383

(57) ABSTRACT

An etch stop layer (ESL) thin-film transistor (TFT) substrate includes an active layer including a channel zone and two opposite side zones that are made conducting through treatment with plasma doping so that a distance between the two side zones is a width of the channel zone that is smaller than a distance between a source electrode and a drain electrode in electrical connection with the two opposite side zones respectively, so as to make a relatively small actual channel length. Such a relatively small actual channel length provides the TFT with an excellent electrical conduction property and has an advantage of increasing a source-drain current.

### BACKGROUND OF THE INVENTION

### 1. Field of the Invention

The present invention relates to the field of display technology, and more particular to an etch stop layer (ESL) thin-film transistor (TFT) substrate and a fabrication method thereof.

### 2. The Related Arts

In the field of display technology, flat panel displays, such as liquid crystal displays (LCDs) and organic light-emitting diode (OLED) displays, have gradually taken the place of cathode ray tube (CRT) displays for wide applications in liquid crystal televisions, mobile phones, personal digital assistants (PDAs), digital cameras, computer monitors, and notebook computer screens.

A display panel is a major component of the LCDs and OLEDs. Both the LCD display panel and the OLED display panel comprise a thin-film transistor (TFT) substrate. Taking the LCD display panel as an example, it is generally made up of a TFT substrate, a color filter (CF), and a liquid crystal arranged between the two substrates. The operation principle is that a driving voltage is applied to the TFT substrate and the CF substrate to control rotation of liquid crystal molecules in order to refract out light from a backlight module to generate an image.

The TFT substrates that are currently available can be categorized, according to the structures thereof, into a number of different types, including: coplanar type, etch stop layer (ESL) type, and back channel etch (BCE) type.

Indium gallium zinc oxide (IGZO) has various advantages, such as high mobility, being suitable for large area production, and easy conversion from amorphous silicon (a-Si), and is becoming a hot spot of study in the field of thin-film transistor technology. However, in an IGZO-TFT, an IGZO active layer is extremely sensitive to processing and environment so that the IGZO-TFT often adopts an ESL structure in order to provide protection to IGZO with the etch stop layer (ESL) and an additionally involved mask. This, however, is adverse to reduction of TFT manufacturing cost. Further, due to a stacked arrangement of source/drain (SD) electrodes and the etch stop layer (ESL), the size of a channel of a TFT device is expanded, leading to lowering of conductivity of the TFT.

Referring to FIG. 1, a known ESL TFT substrate comprises a base plate 100 and a gate electrode 200, a gate insulation layer 300, an oxide semiconductor layer 400, an etch stop layer 500, a source electrode 610, and a drain electrode 620 that are arranged, in sequence, on the base plate 100, wherein the source electrode 610 and the drain electrode 620 are respectively set in engagement with the oxide semiconductor layer 400 through a first via 510 and a second via 520, respectively.

The ESL TFT substrate shown in FIG. 1 involves an etch stop layer 500 to prevent a channel from being damaged. However, due to the addition of the etch stop layer 500, the length of the channel of the TFT is increased, accordingly. In view of a TFT of a BCE structure, the length of the channel is the distance L10 between the source electrode 610 and the drain electrode 620, while in view of a TFT of an ESL structure, the actual channel length L is the distance between the first via 510 and the second via 520. Due to deviation of production accuracy (such as error of alignment in an exposure process and variation of line width in an etching process), the source electrode 610 and the drain electrode 620 must show an overlapping length with respect to the etch stop layer 500 between the first via 510 and the second via 520. This makes the channel length L of an ESL TFT substrate greater than the length of the channel of a BCE TFT substrate. Due to the magnitude of the source-drain current (Ids) being inversely proportional to the channel length, a large channel length L would readily cause lowering of conductivity of the TFT, leading to an issue of relatively small source-drain current.

### SUMMARY OF THE INVENTION

Objectives of the present invention are to provide an etch stop layer (ESL) thin-film transistor (TFT) substrate, which has a relatively small actual channel length so as to provide the TFT with an excellent electrical conduction property and thus overcoming the issue that a known ESL TFT substrate has a relatively small source-drain current.

Objectives of the present invention are also to provide an ESL TFT substrate fabrication method, which reduces an actual channel length of a TFT so as to provide the TFT with an excellent electrical conduction property and thus overcoming the issue that a known ESL TFT substrate has a relatively small source-drain current.

To achieve the above objectives, the present invention provides an ESL TFT substrate, which comprises: a backing plate, a gate electrode arranged on the backing plate, a gate insulation layer arranged on the gate electrode and the backing plate, an active layer arranged on the gate insulation layer and located above and corresponding to the gate electrode, an etch stop layer arranged on the active layer, and a source electrode and a drain electrode arranged on the etch stop layer;

wherein the active layer is formed of a material that comprises a metal oxide semiconductor; the active layer has two opposite side zones that are respectively a source contact zone and a drain contact zone having increased electrical conductivity through plasma doping treatment, such that an area between the source contact zone and the drain contact zone of the active layer defines a channel zone;

the etch stop layer is provided with a first via and second via formed therein and respectively corresponding to the source contact zone and the drain contact zone of the active layer, the source electrode and the drain electrode being set in contact engagement with the source contact zone and the drain contact zone, respectively, through the first via and the second via; and

the channel zone has a width that is smaller than a distance between the source electrode and the drain electrode.

The active layer is formed of a material that comprises indium gallium zinc oxide.

The source contact zone and the drain contact zone of the active layer are subjected to treatment of N type plasma doping.

The gate electrode has a width that is smaller than a width of the active layer.

The ESL TFT substrate further comprises a light-shielding layer arranged under and corresponding to the active layer and the gate electrode and a buffer layer arranged between the backing plate and the gate insulation layer; the gate electrode is located between the buffer layer and the gate insulation layer and the light-shielding layer is located between the backing plate and the buffer layer.

The present invention also provides an ESL TFT substrate fabrication method, which comprises the following steps:

Step S1: providing a backing plate, forming a gate electrode on the backing plate through deposition and patterning, forming a gate insulation layer on the gate electrode and the backing plate through deposition and patterning, forming an active layer on the gate insulation layer through deposition and patterning at a location above and corresponding to the gate electrode; wherein the active layer is formed of a material that comprises a metal oxide semiconductor;

Step S2: forming a protection layer on the active layer through patterning, wherein the protection layer corresponds to and covers a middle area of the active layer to expose two opposite side zones of the active layer, subjecting the two opposite side zones of the active layer that are exposed outside the protection layer to plasma doping treatment to increase electrical conductivity of the two side zones to respectively form a source contact zone and a drain contact zone, wherein the middle area of the active layer that is covered by the protection layer forms a channel zone, and removing the protection layer; and

Step S3: forming an etch stop layer on the active layer and the gate insulation layer through deposition and patterning, such that the etch stop layer is provided with a first via and a second via formed therein and respectively corresponding to the source contact zone and the drain contact zone of the active layer, forming a source electrode and a drain electrode on the etch stop layer through deposition and patterning, wherein the source electrode and the drain electrode are respectively set in contact engagement with the source contact zone and the drain contact zone through the first via and the second via;

wherein the channel zone has a width that is smaller than a distance between the source electrode and the drain electrode.

The active layer formed in Step S1 is formed of a material that comprises indium gallium zinc oxide.

In Step S2, the two side zones of the active layer exposed outside the protection layer are subjected to treatment of N type plasma doping.

The gate electrode has a width that is smaller than a width of the active layer.

Step S1 further comprises, before the formation of the gate electrode, forming a light-shielding layer on the backing plate through deposition and patterning and forming a buffer layer on the light-shielding layer and the backing plate through deposition, such that the gate electrode is formed, afterwards, on the buffer layer at a location above and corresponding to the light-shielding layer.

The present invention further provides an ESL TFT substrate, which comprises: a backing plate, a gate electrode arranged on the backing plate, a gate insulation layer arranged on the gate electrode and the backing plate, an active layer arranged on the gate insulation layer and located above and corresponding to the gate electrode, an etch stop layer arranged on the active layer, and a source electrode and a drain electrode arranged on the etch stop layer;

wherein the active layer is formed of a material that comprises a metal oxide semiconductor; the active layer has two opposite side zones that are respectively a source contact zone and a drain contact zone having increased electrical conductivity through plasma doping treatment, such that an area between the source contact zone and the drain contact zone of the active layer defines a channel zone;

the etch stop layer is provided with a first via and second via formed therein and respectively corresponding to the source contact zone and the drain contact zone of the active layer, the source electrode and the drain electrode being set in contact engagement with the source contact zone and the drain contact zone, respectively, through the first via and the second via; and

the channel zone has a width that is smaller than a distance between the source electrode and the drain electrode;

wherein the active layer is formed of a material that comprises indium gallium zinc oxide;

wherein the source contact zone and the drain contact zone of the active layer are subjected to treatment of N type plasma doping; and

wherein the gate electrode has a width that is smaller than a width of the active layer;

and further comprising a light-shielding layer arranged under and corresponding to the active layer and the gate electrode and a buffer layer arranged between the backing plate and the gate insulation layer; the gate electrode is located between the buffer layer and the gate insulation layer and the light-shielding layer is located between the backing plate and the buffer layer.

The efficacy of the present invention is that the present invention provides an ESL TFT substrate, in which two opposite side zones of an active layer are zones that are made conducting through treatment with plasma doping and the distance between the two side zones is the width of the channel zone that is smaller than a distance between the source electrode and the drain electrode so as to have a relatively small actual channel length, providing the TFT with an excellent electrical conduction property and being advantageous in increasing a source-drain current to thereby overcome the issue of the prior art ESL TFT substrate having a small source-drain current. The present invention provides an ESL TFT substrate fabrication method, in which two opposite side zones of an active layer are zones that are made conducting through treatment with plasma doping and the distance between the two side zones is the width of the channel zone that is smaller than a distance between the source electrode and the drain electrode so as to have a relatively small actual channel length, providing the TFT with an excellent electrical conduction property and being advantageous in increasing a source-drain current to thereby overcome the issue of the prior art ESL TFT substrate having a small source-drain current.

For better understanding of the features and technical contents of the present invention, reference will be made to the following detailed description of the present invention and the attached drawings. However, the drawings are provided only for reference and illustration and are not intended to limit the present invention.

### BRIEF DESCRIPTION OF THE DRAWINGS

The technical solution, as well as other beneficial advantages, of the present invention will become apparent from the following detailed description of embodiments of the present invention, with reference to the attached drawings.

In the drawings:

FIG. 1 is a schematic view illustrating a structure of a conventional etch stop layer (ESL) thin-film transistor (TFT) substrate;

FIG. 2 is a schematic view illustrating a structure of an ESL TFT substrate according to a first embodiment of the present invention;

FIG. 3 is a schematic view illustrating a structure of an ESL TFT substrate according to a second embodiment of the present invention;

FIG. 4 is a flow chart illustrating an ESL TFT substrate fabrication method according to the present invention;

FIG. 5 is a schematic view illustrating Step S1 of the ESL TFT substrate fabrication method according to the first embodiment of the present invention;

FIG. 6 is a schematic view illustrating Step S2 of the ESL TFT substrate fabrication method according to the first embodiment of the present invention;

FIG. 7 is a schematic view illustrating Step S3 of the ESL TFT substrate fabrication method according to the first embodiment of the present invention; and

FIG. 8 is a schematic view illustrating Step S1 of an ESL TFT substrate fabrication method according to the second embodiment of the present invention.

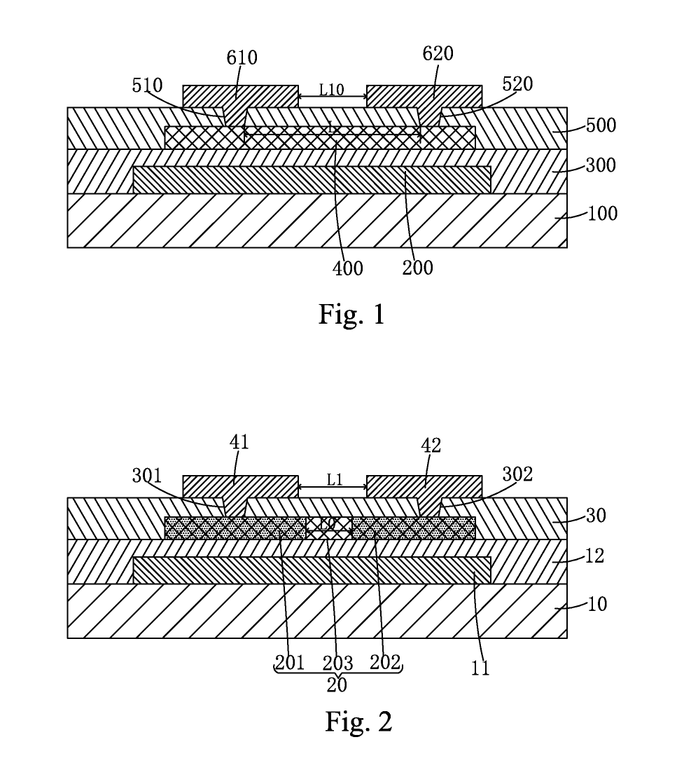

### DETAILED DESCRIPTION OF THE PREFERRED EMBODIMENTS

To further expound the technical solution adopted in the present invention and the advantages thereof, a detailed description will be given with reference to the preferred embodiments of the present invention and the drawings thereof.

Firstly, the present invention providing an etch stop layer (ESL) thin-film transistor (TFT) substrate. FIG. 2 is a schematic view illustrating a structure of an ESL TFT substrate according to a first embodiment of the present invention. The ESL TFT substrate comprises: a backing plate 10, a gate electrode 11 arranged on the backing plate 10, a gate insulation layer 12 arranged on the gate electrode 11 and the backing plate 10, an active layer 20 arranged on the gate insulation layer 12 and located above and corresponding to the gate electrode 11, an etch stop layer 30 arranged on the active layer 20, and a source electrode 41 and a drain electrode 42 arranged on the etch stop layer 30;

wherein the active layer 20 is formed of a material that comprises a metal oxide semiconductor; the active layer 20 has two opposite side zones that are respectively a source contact zone 201 and a drain contact zone 202 having increased electrical conductivity through plasma doping treatment, such that an area between the source contact zone 201 and the drain contact zone 202 of the active layer 20 defines a channel zone 203;

the etch stop layer 30 is provided with a first via 301 and second via 302 formed therein and respectively corresponding to the source contact zone 201 and the drain contact zone 202 of the active layer 20, the source electrode 41 and the drain electrode 42 being set in contact engagement with the source contact zone 201 and the drain contact zone 202, respectively, through the first via 301 and the second via 302;

a distance between the source contact zone 201 and the drain contact zone 202 is a width L0 of the channel zone 203 that is smaller than a distance L1 between the source electrode 41 and the drain electrode 42 so that, compared to the known techniques, the TFT has a relatively small actual channel length thereby providing the TFT with an excellent electrical conduction property to be advantageous in increasing a source-drain current, so as to overcome the issue of the conventional ESL TFT substrate having a small source-drain current.

Specifically, the active layer 20 is formed of a material that comprises indium gallium zinc oxide (IGZO).

Specifically, the source contact zone 201 and the drain contact zone 202 of the active layer 20 are treated with N type plasma doping, such that the source contact zone 201 and the drain contact zone 202 are both n+IGZO zones that are made conducting through treatment with N type plasma doping.

Specifically, the gate electrode 11, the source electrode 41, and the drain electrode 42 are each formed of a material that comprises a metallic material, such as an alloy of one or multiple ones of molybdenum, aluminum, copper, and titanium; the gate electrode 11 has a width that is greater than or equal to a width of the active layer 20 such that two opposite side edges of the active layer 20 are located above locations inboard the gate electrode 11 or are substantially in alignment with two opposite side edges of the gate electrode 11 so that the metallic material of the gate electrode 11 provides effective light shielding to the active layer 20.

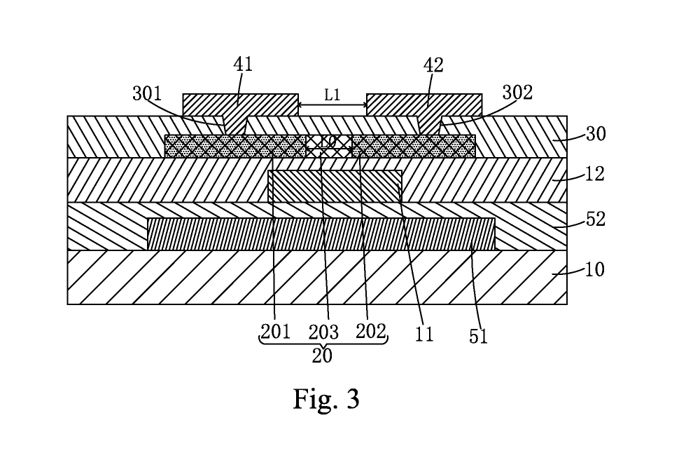

FIG. 3 is a schematic view illustrating a structure of an ESL TFT substrate according to a second embodiment of the present invention. The second embodiment is different from the first embodiment in that the width of the gate electrode 11 is smaller than the width of the active layer 20; the ESL TFT substrate further comprises a light-shielding layer 51 arranged under and corresponding to the active layer 20 and the gate electrode 11 and a buffer layer 52 arranged between the backing plate 10 and the gate insulation layer 12; the gate electrode 11 is located between the buffer layer 52 and the gate insulation layer 12 and the light-shielding layer 51 is located between the backing plate 10 and the buffer layer 52, and further, the light-shielding layer 51 has a width that is greater than or equal to the width of the active layer 20 such that the two opposite side edges of the active layer 20 are both located above locations inboard the light-shielding layer 51 or are substantially in alignment with two opposite side edges of the light-shielding layer 51 so that the light-shielding layer 51 completely covers the active layer 20 from the underside of the active layer 20.

In the present invention, the source contact zone 201 and the drain contact zone 202 are zones that are made conducting through being treated with plasma doping, so that as being set in contact with the source electrode 41 and the drain electrode 42 respectively, they are respectively equivalent to parts of the source electrode 41 and the drain electrode 42 so that actual areas of the source electrode 41 and the drain electrode 42 are increased and as such, parasitic capacitance may be increased. Thus, in the instant embodiment, to prevent an increase of parasitic capacitance resulting from the source contact zone 201 and the drain contact zone 202 being made conducting, the width of the gate electrode 11 is reduced as compared to the prior art so that the width of the gate electrode 11 is made even smaller than the width of the active layer 20.

Further, since the width of the gate electrode 11 is smaller than the width of the active layer 20, meaning the two opposite side edges of the active layer 20 are located above locations that are outboard the gate electrode 11, the instant embodiment requires an additionally arranged light-shielding layer 51 to shield light for the active layer 20 so as to effectively prevent light-induced electrical leakage occurring in the portions of the active layer 20 that are located above locations outboard the gate electrode 11. As such, while reducing the actual channel length of the TFT and increasing the source-drain current, the instant embodiment can effectively reduce parasitic capacitance and prevent light-induced electrical leakage. The remaining is the same as the first embodiment and repeated description will be omitted herein.

The present invention provides an ESL TFT substrate, in which two opposite side zones of an active layer 20 are zones that are made conducting through treatment with plasma doping and the distance between the two side zones is the width L0 of the channel zone 203 that is smaller than a distance L1 between the source electrode 41 and the drain electrode 42 so as to have a relatively small actual channel length, providing the TFT with an excellent electrical conduction property and being advantageous in increasing a source-drain current to thereby overcome the issue of the prior art ESL TFT substrate having a small source-drain current.

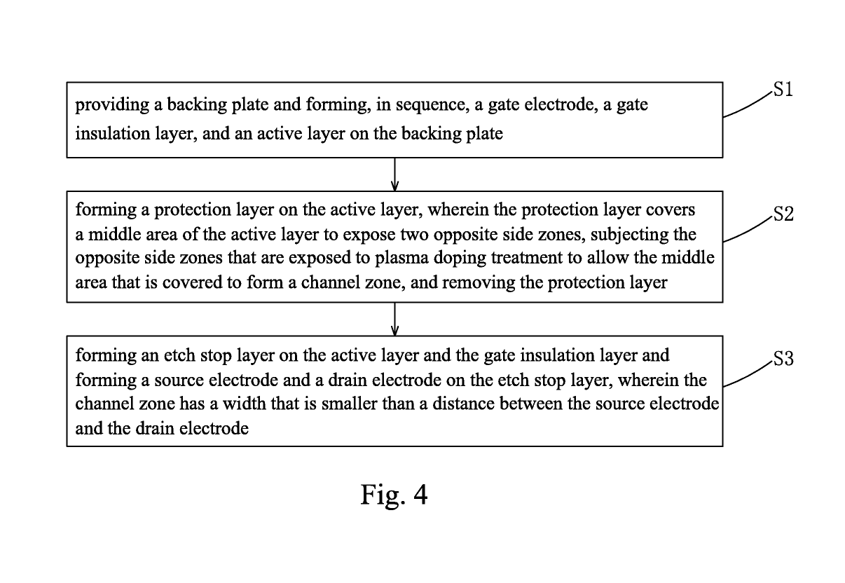

Referring to FIG. 4, based on the above-described ESL TFT substrate, the present invention also provides an ESL TFT substrate fabrication method. The ESL TFT substrate fabrication method of the present invention comprises, as a first embodiment, the following steps:

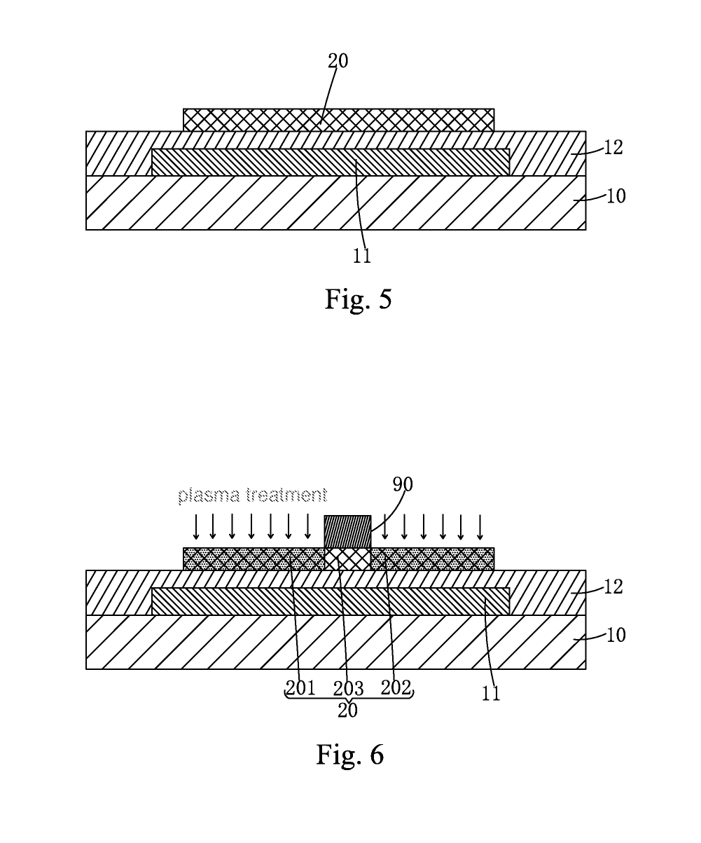

Step S1: as shown in FIG. 5, providing a backing plate 10, forming a gate electrode 11 on the backing plate 10 through deposition and patterning, forming a gate insulation layer 12 on the gate electrode 11 and the backing plate 10 through deposition and patterning, forming an active layer 20 on the gate insulation layer 12 through deposition and patterning at a location above and corresponding to the gate electrode 11; wherein the active layer 20 is formed of a material that comprises a metal oxide semiconductor.

Specifically, the gate electrode 11 is formed of a material that comprises a metallic material, such as an alloy of one or multiple ones of molybdenum, aluminum, copper, and titanium, and is formed through deposition with physical vapor deposition (PVD).

Specifically, in Step S1, processes for forming the gate electrode 11 and the active layer 20 through patterning specifically comprise: a photoresist coating step, an exposure step, a development step, an etching step, and a photoresist removal step; wherein the etching step applied to the gate electrode 11 comprises wet etching and the etching step applied to the active layer 20 comprises dry etching.

Specifically, the gate electrode 11 formed in Step S1 has a width that is greater than or equal to a width of the active layer 20 such that two opposite side edges of the active layer 20 are located above locations inboard the gate electrode 11 or are substantially in alignment with two opposite side edges of the gate electrode 11 so that the metallic material of the gate electrode 11 provides effective light shielding to the active layer 20.

Specifically, the active layer 20 formed in Step S1 is formed of a material that comprises indium gallium zinc oxide.

Specifically, the gate insulation layer 12 is formed of a material that comprises one or multiple ones of silicon oxide (SiOx) and silicon nitride (SiNx). Preferably, the gate insulation layer 12 is formed of a material that comprises silicon oxide.

Specifically, in Step S1, the gate insulation layer 12 is formed through deposition with chemical vapor deposition (CVD).

Step S2: as shown in FIG. 6, forming a protection layer 90 on the active layer 20 through patterning, wherein the protection layer 90 corresponds to and covers a middle area of the active layer 20 to expose two opposite side zones of the active layer 20, subjecting the two opposite side zones of the active layer 20 that are exposed outside the protection layer 90 to plasma doping treatment to increase electrical conductivity of the two side zones to respectively form a source contact zone 201 and a drain contact zone 202, wherein the middle area of the active layer 20 that is covered by the protection layer 90 forms a channel zone 203, and removing the protection layer 90.

Specifically, the protection layer 90 formed in Step S2 is formed of a material that comprises a photoresist material and is formed through a photoresist coating step, an exposure step, and a development step.

Specifically, in Step S2, the two side zones of the active layer 20 that are exposed outside the protection layer 90 are subjected to treatment with N type plasma doping, such that the source contact zone 201 and the drain contact zone 202 are both n+IGZO zones that are made conducting through treatment with N type plasma doping.

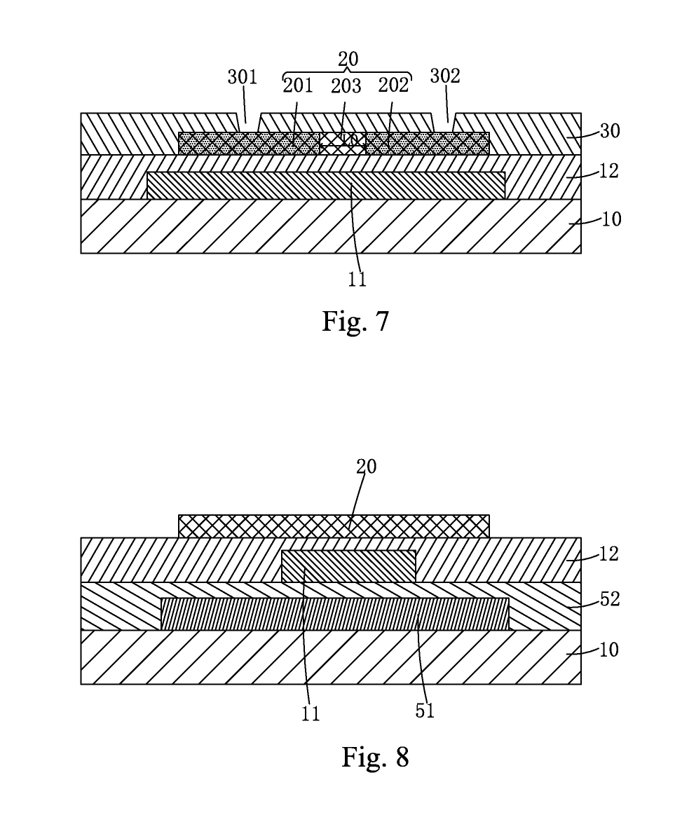

Step S3: as shown in FIG. 7, forming an etch stop layer 30 on the active layer 20 and the gate insulation layer 12 through deposition and patterning, such that the etch stop layer 30 is provided with a first via 301 and a second via 302 formed therein and respectively corresponding to the source contact zone 201 and the drain contact zone 202 of the active layer 20, forming a source electrode 41 and a drain electrode 42 on the etch stop layer 30 through deposition and patterning, wherein the source electrode 41 and the drain electrode 42 are respectively set in contact engagement with the source contact zone 201 and the drain contact zone 202 through the first via 301 and the second via 302 to thereby form the ESL TFT substrate shown in FIG. 2.

Specifically, the channel zone 203 has a width L0 that is smaller than a distance L between the source electrode 41 and the drain electrode 42 so that the TFT has a relatively small actual channel length thereby providing the TFT with an excellent electrical conduction property to be advantageous in increasing a source-drain current, so as to overcome the issue of the conventional ESL TFT substrate having a small source-drain current.

Specifically, in Step S3, the source electrode 41 and the drain electrode 42 are each formed of a material that comprises a metallic material, such as an alloy of one or multiple ones of molybdenum, aluminum, copper, and titanium, which is formed through deposition with physical vapor deposition.

Specifically, in Step S3, the etch stop layer 30 is formed through deposition with chemical vapor deposition.

Specifically, in Step S3, processes for forming the etch stop layer 30, the source electrode 41 and the drain electrode 42 through patterning specifically comprise: a photoresist coating step, an exposure step, a development step, an etching step, and a photoresist removal step; wherein the etching step applied to the source electrode 41 and the drain electrode 42 comprises wet etching and the etching step applied to the etch stop layer 30 comprises dry etching.

An ESL TFT substrate fabrication method according to a second embodiment of the present invention is different from the first embodiment in that, as shown in FIG. 8, Step S1 further comprises, before the formation of the gate electrode 11, forming a light-shielding layer 51 on the backing plate 10 through deposition and patterning and forming a buffer layer 52 on the light-shielding layer 51 and the backing plate 10 through deposition, such that the gate electrode 11 is formed, afterwards, on the buffer layer 52 at a location above and corresponding to the light-shielding layer 51; and the gate electrode 11 formed in Step S1 has a width that is smaller than a width of the active layer 20 and the light-shielding layer 51 has a width that is greater than or equal to the width of the active layer 20. As such, in Step S3 of the instant embodiment, an ESL TFT substrate as shown in FIG. 3 is obtained.

Specifically, the light-shielding layer 51 comprises a metallic material, which is formed through deposition with physical vapor deposition. A process for forming the light-shielding layer 51 through deposition specifically comprises: a photoresist coating step, an exposure step, a development step, an etching step, and a photoresist removal step, wherein the etching step applied to the light-shielding layer 51 comprises wet etching.

Specifically, the buffer layer 52 is formed of a material that comprises one or multiple ones of silicon oxide and silicon nitride. Preferably, the buffer layer 52 is formed of a material that comprises silicon oxide and the buffer layer 52 is formed through deposition with chemical vapor deposition.

In the present invention, the source contact zone 201 and the drain contact zone 202 are zones that are made conducting through being treated with plasma doping, so that as being set in contact with the source electrode 41 and the drain electrode 42 respectively, they are respectively equivalent to parts of the source electrode 41 and the drain electrode 42 so that actual areas of the source electrode 41 and the drain electrode 42 are increased and as such, parasitic capacitance may be increased. Thus, in the instant embodiment, to prevent the issue of increase of parasitic capacitance resulting from the source contact zone 201 and the drain contact zone 202 being made conducting, the width of the gate electrode 11 is reduced as compared to the prior art so that the width of the gate electrode 11 is made even smaller than the width of the active layer 20.

Further, since the width of the gate electrode 11 is smaller than the width of the active layer 20, meaning the two opposite side edges of the active layer 20 are located above locations that are outboard the gate electrode 11, the instant embodiment requires an additionally arranged light-shielding layer 51 to shield light for the active layer 20 so as to effectively prevent light-induced electrical leakage occurring in the portions of the active layer 20 that are located above locations outboard the gate electrode 11. As such, while reducing the actual channel length of the TFT and increasing the source-drain current, the instant embodiment can effectively reduce parasitic capacitance and prevent light-induced electrical leakage. The remaining is the same as the first embodiment and repeated description will be omitted herein.

The present invention provides an ESL TFT substrate fabrication method, in which two opposite side zones of an active layer 20 are zones that are made conducting through treatment with plasma doping and the distance between the two side zones is the width L0 of the channel zone 203 that is smaller than a distance L1 between the source electrode 41 and the drain electrode 42 so as to have a relatively small actual channel length, providing the TFT with an excellent electrical conduction property and being advantageous in increasing a source-drain current to thereby overcome the issue of the prior art ESL TFT substrate having a small source-drain current.

In summary, the present invention provides an ESL TFT substrate, in which two opposite side zones of an active layer are zones that are made conducting through treatment with plasma doping and the distance between the two side zones is the width of the channel zone that is smaller than a distance between the source electrode and the drain electrode so as to have a relatively small actual channel length, providing the TFT with an excellent electrical conduction property and being advantageous in increasing a source-drain current to thereby overcome the issue of the prior art ESL TFT substrate having a small source-drain current. The present invention provides an ESL TFT substrate fabrication method, in which two opposite side zones of an active layer are zones that are made conducting through treatment with plasma doping and the distance between the two side zones is the width of the channel zone that is smaller than a distance between the source electrode and the drain electrode so as to have a relatively small actual channel length, providing the TFT with an excellent electrical conduction property and being advantageous in increasing a source-drain current to thereby overcome the issue of the prior art ESL TFT substrate having a small source-drain current.

Based on the description given above, those having ordinary skills in the art may easily contemplate various changes and modifications of the technical solution and the technical ideas of the present invention. All these changes and modifications are considered belonging to the protection scope of the present invention as defined in the appended claims.

1. An etch stop layer (ESL) thin-film transistor (TFT) substrate, comprising:
a backing plate,
a gate electrode arranged on the backing plate,
a gate insulation layer arranged on the gate electrode and the backing plate,
an active layer arranged on the gate insulation layer and located above and corresponding to the gate electrode,
an etch stop layer arranged on the active layer, and
a source electrode and a drain electrode arranged on the etch stop layer;
wherein the active layer is formed of a material that comprises a metal oxide semiconductor; the active layer has two opposite side zones that are respectively a source contact zone and a drain contact zone having increased electrical conductivity through plasma doping treatment, such that an area between the source contact zone and the drain contact zone of the active layer defines a channel zone;
the etch stop layer is provided with a first via and a second via that are formed in the etch stop layer and respectively corresponding to the source contact zone and the drain contact zone of the active layer, the source electrode and the drain electrode being set in contact engagement with the source contact zone and the drain contact zone, respectively, through the first via and the second via; and
the channel zone has a width that is smaller than a distance between the source electrode and the drain electrode;
wherein the gate electrode has a width that is greater than or equal to a width of the active layer that includes the channel zone, the source contact zone, and the drain contact zone, such that two opposite side edges of the active layer are located inboard the gate electrode or are substantially in alignment with two opposite side edges of the gate electrode.

2. The ESL TFT substrate according to claim 1, wherein the material of the active layer comprises indium gallium zinc oxide.

3. The ESL TFT substrate according to claim 1, wherein the source contact zone and the drain contact zone of the active layer are subjected to treatment of N type plasma doping.

4-5. (canceled)

6. An etch stop layer (ESL) thin-film transistor (TFT) substrate fabrication method, comprising the following steps:
Step S1: providing a backing plate, forming a gate electrode on the backing plate through deposition and patterning, forming a gate insulation layer on the gate electrode and the backing plate through deposition and patterning, forming an active layer on the gate insulation layer through deposition and patterning at a location above and corresponding to the gate electrode; wherein the active layer is formed of a material that comprises a metal oxide semiconductor;
Step S2: forming a protection layer on the active layer through patterning, wherein the protection layer corresponds to and covers a middle area of the active layer to expose two opposite side zones of the active layer, subjecting the two opposite side zones of the active layer that are exposed outside the protection layer to plasma doping treatment to increase electrical conductivity of the two side zones to respectively form a source contact zone and a drain contact zone, wherein the middle area of the active layer that is covered by the protection layer forms a channel zone, and removing the protection layer; and
Step S3: forming an etch stop layer on the active layer and the gate insulation layer through deposition and patterning, such that the etch stop layer is provided with a first via and a second via formed therein and respectively corresponding to the source contact zone and the drain contact zone of the active layer, forming a source electrode and a drain electrode on the etch stop layer through deposition and patterning, wherein the source electrode and the drain electrode are respectively set in contact engagement with the source contact zone and the drain contact zone through the first via and the second via;
wherein the channel zone has a width that is smaller than a distance between the source electrode and the drain electrode.

7. The ESL TFT substrate fabrication method according to claim 6, wherein the active layer formed in Step S1 is formed of a material that comprises indium gallium zinc oxide.

8. The ESL TFT substrate fabrication method according to claim 6, wherein in Step S2, the two side zones of the active layer exposed outside the protection layer are subjected to treatment of N type plasma doping.

9. The ESL TFT substrate fabrication method according to claim 6, wherein the gate electrode has a width that is smaller than a width of the active layer.

10. The ESL TFT substrate fabrication method according to claim 9, wherein Step S1 further comprises, before the formation of the gate electrode, forming a light-shielding layer on the backing plate through deposition and patterning and forming a buffer layer on the light-shielding layer and the backing plate through deposition, such that the gate electrode is formed, afterwards, on the buffer layer at a location above and corresponding to the light-shielding layer.

11. (canceled)
